(19) United States
(12) Patent Application Publication
(10) Pub. No.: US 2011/0124149 A1
(43) Pub. Date: May 26, 2011

(54) METHOD AND DEVICE FOR COATING A CARRIER FOR THIN-FILM SOLAR CELLS

(75) Inventor: Martin Schoch, Freudenstadt-Kniebis (DE)

(73) Assignee: GEBR. SCHMID GMBH & CO., Freudenstadt (DE)

(21) Appl. No.: 12/738,944

(22) Filed: Apr. 20, 2010

Related U.S. Application Data
(63) Continuation of application No. PCT/EP2008/008877, filed on Oct. 21, 2008.

(30) Foreign Application Priority Data
Oct. 22, 2007 (DE) 10 2007 052 237.3

(51) Int. Cl. H01L 31/0256; B05C 3/02

(52) U.S. Cl. 438/95; 118/423; 257/E31.003

(57) ABSTRACT

A system (11) is designed to coat a film-like, long carrier (18) for thin-film solar cells on the absorber layer thereof with cadmium sulfide. To this end, the carrier (18) is continuously guided through a solution (23) made of cadmium acetate, ammonia and thiourea or is immersed into a bath (22) with said solution (23). By using a wide, very long and flat tub (24) containing the solution (23), the required amount for the coating is minimized, such that the consumption of solution (23) is low.

### FIELD OF APPLICATION AND PRIOR ART

This application is a §371 national stage of PCT/EP2008/008877, filed Oct. 21, 2008, which claims priority to German Patent Application No. 10 2007 052 237.3, filed Oct. 22, 2007, both of which are hereby incorporated by reference.

The invention relates to a method for coating a carrier or substrate for thin-film solar cells with cadmium sulfide onto an absorber layer on the carrier, and to a device or installation suitable for carrying out this method.

One promising branch of thin-film technology for thin-film solar cells is based on the use of chalcopyrite compounds as absorber layer. Combinations of the elements copper, indium, gallium, sulfur and selenium are involved. These elements can be doped appropriately in different stoichiometric compositions for photovoltaics. The most common compounds are CuInSe₂ and CuInS₂, which are also designated by the abbreviations CIS and CIGS.

On a carrier substrate, e.g. a glass sheet or else flexible materials such as metal or plastic films, firstly a conductive layer is deposited. Various methods are used for applying the CIS absorber layer; by way of example, it can be applied sequentially with subsequent homogenization or be vapor-deposited directly in a corresponding mixture. As an alternative to CIS compounds, cadmium telluride can also be used as a p-doped absorber layer.

In order to produce a photoactive semiconductor structure, a further n-doped layer is additionally required on the CIS absorber layer. The prior art involves a coating with cadmium sulfide, which coating is deposited on the CIS absorber layer in a wet-chemical bath.

A solution comprising a mixture of cadmium acetate, ammonia and thiourea is prepared for coating the CIS/CdTe absorber layer. The deposition reaction starts at a temperature of approximately 50° C. The process is usually conducted at 60° C. The required layer thickness of 50 nm is attained after approximately 10 minutes.

The reaction in the solution is ended after approximately 20 minutes, the cadmium precipitates completely as cadmium sulfide and can no longer be used for coating. To date, it has not yet been possible to implement this process continuously by admixing additional chemicals; therefore, the known processes are all based on a batch method, that is to say that the substrates are transported item by item into a coating installation and coated there with a smallest possible liquid volume and then rinsed and dried. The spent reaction solution is discarded. These batch methods are of only limited suitability for the coating of films, for example, which are usually processed from roll to roll.

### OBJECT AND HOW IT IS ACHIEVED

The invention is based on the object of providing a method mentioned in the introduction and also a device mentioned in the introduction with which problems in the prior art can be avoided and, in particular, a better and more efficient coating of a stated carrier with cadmium sulfide can be effected in conjunction with a lower consumption of chemicals.

This object is achieved by means of a method comprising the features of claim 1 and also a device comprising the features of claim 20. Advantageous and preferred configurations of the invention are the subject matter of the further claims and are explained in greater detail below. Although some of the features below are mentioned only for the method or the device, irrespective of this they are intended to be applicable or usable both for the method and for the device. The wording of the claims is incorporated by express reference in the content of the description. Furthermore, the wording of the German priority application DE 102007052237.3 of Oct. 22, 2007 in the name of the same applicant is incorporated by express reference in the content of the present description.

It is provided that the carrier, at least at the absorber layer to be coated, is wetted with a solution from which cadmium sulfide is intended to be precipitated onto the absorber layer. Such a solution is preferably composed of cadmium acetate, ammonia and thiourea. Corresponding compositions are familiar to a person skilled in the art.

According to the invention, the carrier is dipped into a bath with the solution and guided in continuous or quasi-continuous transport through the bath. In this case, at least the absorber layer is permanently wetted with the solution in the bath, with the result that a good coating with cadmium sulfide is possible. In this case, the quantity of the solution in the bath is relatively small, which is achieved by means of a low solution filling level. The consumption of solution or the chemicals contained therein is thus kept low. A movement of the carrier through the bath has the advantage that a certain intermixing of the solution is effected and, as it were, the solution wetting the carrier surface is exchanged or is not always the same.

Advantageously, the low solution filling level in the bath can be a few millimeters, particularly advantageously 3 to 20 millimeters, for example 5 to 10 millimeters. In this case, the solution or the bath can be provided in a tub and the latter can be somewhat wider than a carrier and can have a length of a number of meters.

In one configuration of the invention, not just the absorber layer to be coated is wetted with the solution, rather the entire carrier is immersed into the bath and guided through the latter. The wetting time or dipping time should be a few minutes, advantageously approximately 10 minutes. A layer thickness of the cadmium sulfide of approximately 50 nm can thus be achieved, which is regarded as advantageous from a functional standpoint.

The carrier can advantageously be transported through the bath at a slow speed and be moved continuously in the process. This is advantageous particularly when the carriers used are not platelike carriers but rather elongated carriers or films which are unrolled from a roll, guided through the solution bath for the purpose of coating with cadmium sulfide and subsequently rolled up again. In this case, the speed is preferably coordinated such that, for a certain immersion length or length of the solution bath, a corresponding residence duration is achieved for a sufficient coating with cadmium sulfide.

A transport of the carriers can advantageously proceed at a higher level upstream of the bath and at least briefly downstream of the bath, or out of the bath, than in the bath itself. This simplifies introduction and discharge and also the construction of a tub with the solution bath therein. A carrier can be lowered for immersion into the bath, or run obliquely downward, which is particularly easy in the case of said filmlike carriers and can be realized by rollers or roller conveyors. Through the bath, the carrier advantageously moves approximately on one plane or horizontally. At the end of the bath, said carrier can be raised again or moved in a manner running obliquely out of the bath.

The abovementioned rollers can also be provided in the bath. The number and arrangement should be determined such that the carrier always runs in an advantageous position, usually horizontally in the bath.

Such a filmlike carrier can be very thin with a plastic film, for example with a thickness of approximately 20 μm to 30 μm. Given a width of one or a few meters, its length can be many meters, for example up to hundreds of meters.

It is advantageous for the carrier to be in the solution bath and transported through the latter with the absorber layer downward. This means that deposits, in particular precipitated cadmium sulfide in small fragments or parts, cannot be taken up on the absorber layer, but rather at most on the rear side, where they can, however, easily be removed again after coating, for example by light brushing, a spraying system or the like. At this point in time it is usually the case that the rear side of such carriers for thin-film solar cells is not yet being used at least from a functional standpoint and is therefore also mechanically robust enough that brushing-away or the like is readily possible.

In one configuration of the invention, the solution in the bath can be cyclically renewed. In this case, respectively all of the solution can be completely drained if it is regarded as spent, and can be replaced by new, unused solution. Such draining of the, as it were, spent solution can be effected approximately every 20 minutes, for example, since in the context of the development work with respect to the present invention, it has been found that the coating rate then decreases greatly.

In an alternative configuration of the invention, the solution in the bath can be permanently renewed. For this purpose, part of the solution can constantly be removed and replaced by new, unused solution. In this case, the rate of exchange can be such that at least every 20 minutes the solution is completely replaced, at least in theory. This configuration affords the advantage that the solution has a composition that is always approximately the same and a coating process can proceed with parameters that are always the same.

It is possible to filter the solution in the bath. Permanent filtering is advantageously possible in the case of an above-described circulation of the solution, during which it is guided out of the bath. By way of example, precipitated cadmium sulfide in the form of small parts or fragments can be filtered out in this case.

As described in the introduction, the bath with the solution is preferably heated in order to start the deposition of cadmium sulfide. Heating is advantageously effected to a temperature of 50° C. to 65° C., particularly advantageously to approximately 60° C. One possibility for heating the solution or a bath with the solution therein consists in surrounding said bath, for example with a large flat tub, with a heated water bath or arranging it in a heated water bath. Consequently, it is not necessary to arrange a heating system directly in the coating solution or on the outer side of said tub. Furthermore, a very uniform and also continuous heating is possible by means of heating in a water bath since temperature fluctuations are compensated for by the heat capacity of the water. The water bath can either be heated directly or else in turn be supplied with heated water from a water supply or a water tank. Such a water tank can be arranged below the water bath together with tub with solution and project beyond it on at least one side, advantageously on all sides. Where the water tank projects beyond the water bath, an overflow can be provided. It is thus possible to pump into the water bath heated water from the water tank with a water volume that is again very much greater by comparison with the water bath, together with heating. The displaced water is then directed back into the water tank via the overflow, such that a type of circuit is possible.

For a continuous and uniform heating of the solution, the temperature thereof can advantageously be measured continuously. For this purpose, a temperature sensor can project into the solution. As an alternative or in addition, the temperature of the water bath or of the water tank can be measured and then set to a value such that the solution has a desired temperature after heating by the water bath.

In addition, the solution state in the bath can be constantly checked. A filling level sensor that projects into the bath can be used for this purpose. This is advantageous both when the solution is replaced continuously and when the solution is replaced at intervals.

It is recommendable to clean the installation at certain time intervals. An acid-containing cleaning solution comprising 5% hydrochloric acid, for example, can be used for this purpose. This cleaning solution can be passed into the bath and/or a tub for the bath and be circulated for a time by means of a pump in order to remove the cadmium sulfide that deposits on all surfaces of the installation and lines. As a result of the circulation of the cleaning solution, the entire installation is purged of cadmium sulfide deposits. Finally, the cleaning solution is drained and disposed of. The installation can then subsequently be rinsed thoroughly with water in order to remove any residues of the cleaning solution.

A tub for the bath is advantageously composed of metal, in particular in order to provide a good heat transfer from a surrounded water bath. For durability to withstand the chemicals used, the tub is advantageously coated with titanium or can consist completely of titanium.

The coating device can have a substantially closed, elongated housing, in which the coating takes place. The housing can have introduction locks and discharge locks for the carriers. The purpose of these locks is to ensure that the temperature in the housing is to an extent well maintained by a water bath and/or heater water tank situated in the housing. This not only saves energy but also simultaneously provides for a corresponding preheating of the carriers directly after introduction into the housing, which likewise improves the coating with cadmium sulfide.

These and further features emerge not only from the claims but also from the description and the drawing, wherein the individual features can be realized in each case by themselves or as a plurality in the form of subcombination in an embodiment of the invention and in other fields and can constitute advantageous and inherently protectable embodiments for which protection is claimed here. The subdivision of the application into individual sections and sub-headings do not restrict the general validity of the statements made thereunder.

### BRIEF DESCRIPTION OF THE DRAWING

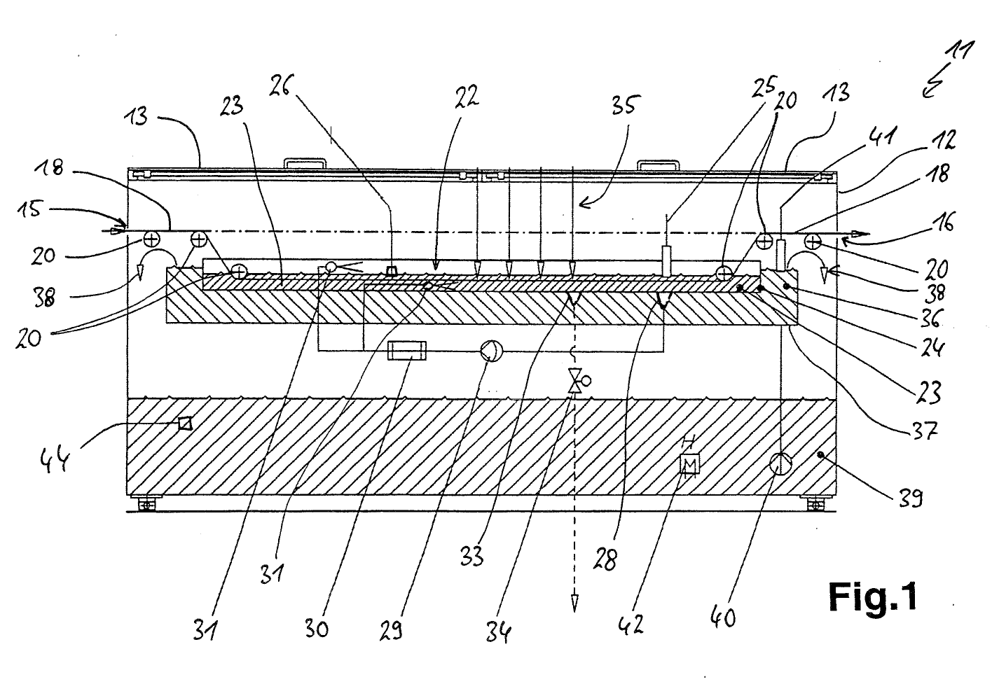

An exemplary embodiment of the invention is illustrated schematically in the drawing and is explained in greater detail below. In this case, FIGURE 1 shows a schematic side view of a coating installation according to the invention for filmlike carriers for thin-film solar cells which run through a flat coating bath.

### DETAILED DESCRIPTION OF THE EXEMPLARY EMBODIMENT

FIGURE 1 illustrates a coating installation 11 according to the invention, comprising a housing 12, which has cover flaps 13 on its top side. The housing has an introduction lock system 15 on the left and a discharge lock system 16 on the right, for example in the form of narrow slots, under certain circumstances provided with curtains or the like. A filmlike carrier 18 runs on rollers 20 into the housing 12 on the left through the introduction lock system 15 and out of said housing again on the right through the discharge lock system 16. Such filmlike carriers 18 for thin-film solar cells are indeed known to the person skilled in the art as has been explained above. In this case, an absorber layer—already present on the carrier 18—together with a layer of cadmium telluride applied thereto or a CIS absorber layer is directed downward or faces downward. However, it can also face upward.

The filmlike carrier 18 therefore runs from the left into the housing 12 and is then diverted downward by means of the rollers 20 from a higher transport plane, which is illustrated by a dash-dotted line in the housing 12 as well, into a bath 22 with a solution 23 in a tub 24 of the bath. In this case, the solution is an abovementioned mixture composed of cadmium acetate, ammonia and thiourea in order to deposit cadmium sulfide therefrom onto the absorber layer after heating. In this case, the carrier 18 runs through the bath 22 with the solution 23 continuously and at a very low speed. In this case, the speed can be approximately 0.5 cm per second, resulting in a residence time of approximately 10 minutes given a length of 3 meters of the immersed carrier. A coating with cadmium sulfide with a thickness of approximately 50 nm is effected as a result. For an installation having a greater length, a plurality of chambers would be provided.

The tub 24 for the bath 22 additionally has a filling level sensor 25 and a temperature sensor 26. This will be discussed in even greater detail below.

Furthermore, a drain 28 is provided at the tub 24, said drain leading to a circulating pump 29, a filter 30 and a plurality of inflow pipes 31, by means of which removed solution 23 is fed back into the bath 22 again after filtering. The inflow pipe 31 can be above the solution 23, as illustrated, or in the middle of the solution. As a result, an improvement of the circulation of the solution 23 is additionally possible for a better coating result, primarily with regard to the coating quality and also somewhat with regard to faster coating.

The bath 22 or the tub 24 thereof additionally has an outlet 33 with an outlet valve 34. After a specific time, spent solution 23 can thus be drained from the bath 22 and replaced by new solution. All new inflows take place from above.

The bath 22 or the tub 24 is situated in a water bath 36 with a tub 37. The water bath 36 is heated and thus heats the bath 22 with the solution 23 to a desired temperature, which can then be monitored by means of the temperature sensor 26. However, an overflow 38 toward the left and toward the right or advantageously on all sides of the tub 37 is provided. In this case, outflowing water from the water bath 36 can run into a water tank 39 arranged underneath, which occupies virtually the entire base surface of the housing 12. By means of a water pump 40, heated water is pumped from the water tank 39 into the tub 37 and has the effect that the water bath 36 is maintained at a desired temperature. For this purpose, a heating system 42 of any desired design, advantageously electric of course, is situated in the water tank 39. The temperature in the water tank 39 is monitored by a temperature sensor 44, such that overall a temperature regulation of the solution 23 to an optimum or desired temperature is effected both by means of the temperature sensor 26 in the solution and by means of the temperature sensor 44 in the water tank 39. In addition, a filling level sensor 41 can be provided in the water bath 36, said sensor monitoring the sufficient filling level in the water bath.

What can be achieved by means of the installation 11 illustrated is that the filmlike carriers 18 for thin-film solar cells are coated with cadmium sulfide in continuous operation. In this case, it suffices for the filling level in the bath 22 to be low, for example a few mm, as long as the underside of the carrier 18 is wetted or immersed in the solution 23. If the filmlike carrier 18 sags to an excessively great extent over the length of the bath 22, then it is possible, instead of further rollers 20, which would possibly be bad here for a coating, to prevent a flow thereon from below with further inflow pipes 31 or the like. In this case, the solution 23 can additionally be circulated at the same time. Furthermore, circulation of the solution 23 can be effected by means of drain 28 and circulating pump 29. By means of the outlet 33 and the outlet valve 34 it is likewise possible to remove at least old or spent solution 23, the quantity of which is then balanced again by means of the inflow, in a manner regulated by the filling level sensor 25.

The illustrated manner of heating the bath 22 or the solution 23 with the water bath 36 has the abovementioned advantages of a very uniform and readily controllable temperature. At the same time, a temperature close to the 60° C. for the solution 23 is achieved in the entire housing 12, with the result that the carrier 18 entering on the left through the introduction lock system 15 is also correspondingly preheated actually prior to immersion into the bath 22. This, too, is advantageous for the coating.

Downstream of the discharge lock system 16 provision may be made for freeing at least the side without an absorber layer, that is to say here the rear side, of the carrier 18 from cadmium sulfide particles and particles. Brushes, for example rotating spiral brushes in a brushing module, can be provided for this purpose. This can be supported by spraying units. Primarily the absorber side of the carrier 18, which in this case faces downward, should only be cleaned by spraying or washing; under certain circumstances, a very soft brush is also employed.

With respect to the above-described cleaning process, it is possible, for example likewise by means of an inflow, for fresh cleaning solution to be admitted into the bath 22 or the tub 24 and circulated by means of the circulating pump 29. In this case, the installation is cleaned of cadmium sulfide coatings or other precipitations. Finally, the cleaning solution can be removed at the outlet 33.

As an alternative to a filmlike carrier 18 illustrated, rigid or less flexible carriers or substrates, for example composed of thin glass or the like, can also be coated by means of an installation of this type. Instead of the diversion by means of the rollers 20 with a relatively large angle, either less oblique introduction of the substrates or the carriers into the bath 22 can be effected or, as an alternative, they can enter into the housing 12 from the left through an introduction lock system 15 and then be lowered from a transport plane onto a roller conveyor or the like in the bath 22, for example by means of grippers. They are then transported there in a predetermined time from left to right through the bath and then, toward the right-hand end, raised by grippers again and removed again on the transport plane through the discharge lock system 16. Apart from the lowering and raising of the carriers into and out of the bath 22, in this case as well continuous transport through the bath is then present and continuous coating is thus present.

1. A method for coating a carrier or substrate for thin-film solar cells with cadmium sulfide onto an absorber layer of said carrier, wherein said carrier, at least at said absorber layer to be coated, is wetted with a solution composed of cadmium acetate, ammonia and thiourea for precipitation of cadmium sulfide, wherein said carrier is dipped into a bath made up of said solution and is guided in a continuous transport through said bath, wherein at least said absorber layer is permanently wetted with said solution in said bath, and wherein a quantity of said solution in said bath is relatively small as a result of a low solution filling level.

2. The method as claimed in claim 1, wherein said solution filling level in a tub for said bath with said solution is a few millimeters.

3. The method as claimed in claim 2, wherein said solution filling level in a tub for said bath with said solution is 3 to 20 millimeters.

4. The method as claimed in claim 1, wherein said carrier is transported in its entirety through said bath in an immersed fashion and wherein said carrier is wetted for approximately 10 minutes until a layer thickness of approximately 50 nm is formed.

5. The method as claimed in claim 1, wherein said carrier is transported through said bath at a slow speed and continuously.

6. The method as claimed in claim 1, wherein said transport plane of said carrier upstream of said bath is at a higher level than through said bath, wherein said carrier is lowered into said bath and moved out and raised again at an end of said bath for transport away from said bath on a higher transport plane than in said bath.

7. The method as claimed in claim 1, wherein there is a transport of said carrier by means of roller conveyors.

8. The method as claimed in claim 1, wherein said carrier is flexible and thin.

9. The method as claimed in claim 1, wherein said carrier is a film-like carrier with a very large length in comparison with its width, wherein said length exceeds that of said bath by a multiple.

10. The method as claimed in claim 1, wherein said carrier is transported with said absorber layer downward in a manner lying substantially horizontally through said bath with said solution.

11. The method as claimed in claim 1, wherein said carrier is transported with said absorber layer upward in a manner lying substantially horizontally through said bath with said solution.

12. The method as claimed in claim 1, wherein said solution is moved and circulated in said bath.

13. The method as claimed in claim 1, wherein said solution in said bath is cyclically renewed by complete draining of spent solution and replacement by new, unused solution, wherein a complete draining is effected approximately every 20 minutes.

14. The method as claimed in claim 1, wherein said solution in the bath is permanently renewed by constant draining of part of said solution and replacement of precisely this part of said solution by new, unused solution.

15. The method as claimed in claim 1, wherein said solution in said bath is filtered during circulation, wherein precipitated cadmium sulfide is filtered out of said solution during filtering.

16. The method as claimed in claim 1, wherein said bath with said solution is heated and wherein said bath with said solution is heated by virtue of the fact that it is situated in a tub and said tub is arranged in a heated water bath, wherein said water bath is supplied with heated water from an underlying water tank, which projects beyond said overlying water bath together with said tub with said solution therein on several sides sides, wherein said water bath has an overflow into said water tank.

17. The method as claimed in claim 1, wherein said solution filling level of said bath is constantly checked.

18. The method as claimed in claim 1, wherein said temperature of the solution is measured continuously and correspondingly readjusted to a desired temperature value of said solution.

19. The method as claimed in claim 1, wherein, for cleaning an installation for performing the method, an acid-containing cleaning solution is passed into said bath and circulated for a time by means of a pump and in said process wets and cleans said bath, wherein, finally, said cleaning solution is drained and rinsing with water is subsequently effected in order to remove residues of said cleaning solution.

20. A device for carrying out said method as claimed in claim 1, wherein a coating installation has a flat tank as bath for receiving said solution with rollers or roller conveyors therein for transporting said carrier through said bath.

21. The device as claimed in claim 20, wherein it has a substantially closed housing having introduction locks and discharge locks for said carrier.

22. The device as claimed in claim 20, wherein at least one filling level sensor is provided in said tub.

23. The device as claimed in claim 20, wherein said transport plane of said carrier upstream of said bath is at a higher level than through said bath, wherein said carrier, having been lowered, runs into said bath and, having been moved out and raises again at an end of said bath and runs for transport away from said bath on a once again higher transport plane.

24. The device as claimed in claim 20, wherein there is provided a filter unit for the solution in the bath for permanent filtration with circulation.

25. The device as claimed in claim 20, wherein there is provided a heating unit for heating said bath with said solution in a tub, wherein said tub is arranged in a heated water bath.

26. The device as claimed in claim 25, wherein an underlying water tank with heated water is arranged under said water bath in order to supply said water bath, wherein said water tank projects beyond said overlying water bath together with said tub with solution therein on all sides, wherein said water bath has an overflow into said underlying water tank.
